(19) United States
(12) Patent Application Publication
(10) Pub. No.: US 2025/0379060 A1
(43) Pub. Date: Dec. 11, 2025

(54) ETCHING METHOD, METHOD OF MANUFACTURING SEMICONDUCTOR DEVICE, PROCESSING APPARATUS, AND RECORDING MEDIUM

(71) Applicant: Kokusai Electric Corporation, Tokyo (JP)

(72) Inventors: Ryuji Yamamoto, Tokyo (JP); Kimihiko Nakatani, Toyama-shi (JP)

(73) Assignee: Kokusai Electric Corporation, Tokyo (JP)

(21) Appl. No.: 19/308,545

(22) Filed: Aug. 25, 2025

Related U.S. Application Data
(63) Continuation of application No. PCT/JP2023/010698, filed on Mar. 17, 2023.

(51) Int. Cl. H01L 21/3065; H01L 21/67

(52) U.S. Cl. CPC H01L 21/3065; H01L 21/67069

(57) ABSTRACT

There is provided a technique that includes performing a cycle a predetermined number of times, the cycle including: (a) supplying a modifying agent to a substrate including a first base and a second base on a surface of the substrate to form an inhibitor layer on a surface of the second base; (b) supplying an altering agent to the substrate to alter at least a portion of the first base, a molecular structure of the altering agent being different from a molecular structure of the modifying agent; and (c) supplying an etching agent to the substrate to etch at least a portion of an altered portion of the first base.

### CROSS-REFERENCE TO RELATED APPLICATION

The application is a Bypass Continuation Application of PCT International Application No. PCT/JP2023/010698, filed on Mar. 17, 2023 and designating the United States, the entire content of which is incorporated herein by reference.

### TECHNICAL FIELD

The present disclosure relates to an etching method, a method of manufacturing a semiconductor device, a processing apparatus, and a recording medium.

### BACKGROUND

In the related art, as a process of manufacturing a semiconductor device, a process of removing a base, which is exposed on a surface of a substrate, by etching is often carried out.

However, depending on a combination of an etching agent, which is used in etching, and a film to be etched, it may not be possible to perform stable etching with good controllability.

### SUMMARY

Some embodiments of the present disclosure provide a technique capable of performing etching with good controllability and stability.

According to an embodiment of the present disclosure, there is provided a technique that includes: performing a cycle a predetermined number of times, the cycle including: (a) supplying a modifying agent to a substrate including a first base and a second base on a surface of the substrate to form an inhibitor layer on a surface of the second base; (b) supplying an altering agent to the substrate to alter at least a portion of the first base, a molecular structure of the altering agent being different from a molecular structure of the modifying agent; and (c) supplying an etching agent to the substrate to etch at least a portion of an altered portion of the first base.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a processing apparatus suitably used in embodiments of the present disclosure, in which a portion of a process furnace is shown in a vertical cross section.

FIG. 2 is a schematic configuration view of a vertical process furnace of a processing apparatus suitably used in embodiments of the present disclosure, in which a portion of the process furnace is shown in a cross section taken along line A-A in FIG. 1.

FIG. 3 is a schematic configuration diagram of a controller of a processing apparatus suitably used in embodiments of the present disclosure, in which a control system of the controller is shown in a block diagram.

FIG. 4A is a schematic cross-sectional view showing a surface portion of a wafer including a first base and a second base on a surface of the wafer. Further, FIG. 4A shows an example in which the first base and the second base are alternately stacked with being adjacent to each other, each of which is adjacent to a third base.

FIG. 4B is a schematic cross-sectional view showing the surface portion of the wafer after forming an inhibitor layer on a surface of the second base by performing step A from a state of FIG. 4A.

FIG. 4C is a schematic cross-sectional view showing the surface portion of the wafer after altering at least a portion of the first base by performing step B from a state of FIG. 4B.

FIG. 4D is a schematic cross-sectional view showing the surface portion of the wafer after etching at least a portion of an altered portion of the first base by performing step C from a state of FIG. 4C.

FIG. 5A is a schematic cross-sectional view showing the surface portion of the wafer after forming an inhibitor layer on an exposed surface of the second base by performing step A from a state of FIG. 4D.

FIG. 5B is a schematic cross-sectional view showing the surface portion of the wafer after altering at least a portion of the first base by performing step B from a state of FIG. 5A.

FIG. 5C is a schematic cross-sectional view showing the surface portion of the wafer after etching at least a portion of an altered portion of the first base by performing step C from a state of FIG. 5B.

FIG. 5D is a schematic cross-sectional view showing the surface portion of the wafer after removing the inhibitor layer remaining on the surface of the second base by performing step D from a state of FIG. 5C.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiments of the Present Disclosure

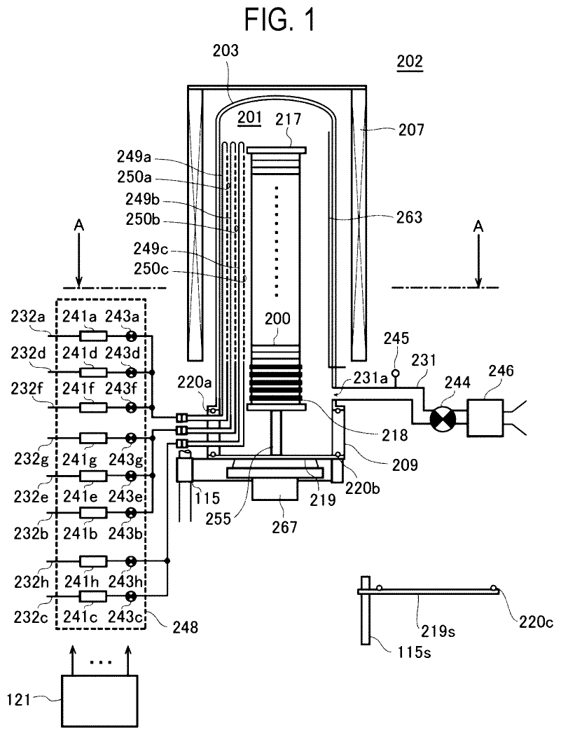

Embodiments of the present disclosure will now be described mainly with reference to FIGS. 1 to 3, 4A to 4D, and 5A to 5D. The drawings used in the following description are schematic, and dimensional relationship, ratios, and the like of various elements shown in the drawings may not match actual ones. Further, dimensional relationships, ratios, and the like of various elements among plural figures may not match each other.

### (1) Configuration of Processing Apparatus

As shown in FIG. 1, a process furnace 202 of a processing apparatus includes a heater 207 as a temperature regulator (a heating part). The heater 207 is formed in a cylindrical shape and is supported by a support plate so as to be vertically installed. The heater 207 also functions as an activator (an exciter) when thermally activating (exciting) a gas.

A reaction tube 203 is disposed inside the heater 207 to be concentric with the heater 207. The reaction tube 203 is made of, for example, a heat resistant material such as quartz (SiO₂) or silicon carbide (SiC), and formed in a cylindrical shape with its upper end closed and its lower end opened. A manifold 209 is disposed to be concentric with the reaction tube 203 under the reaction tube 203. The manifold 209 is made of, for example, a metal material such as stainless steel (SUS), and formed in a cylindrical shape with both of its upper and lower ends opened. The upper end of the manifold 209 engages with the lower end portion of the reaction tube 203 so as to support the reaction tube 203. An O-ring 220a serving as a seal is installed between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical area of the process container. The process chamber 201 is configured to be capable of accommodating a plurality of wafers 200 as substrates. Processing on the wafers 200 is performed in the process chamber 201.

Nozzles 249a to 249c as first to third suppliers are installed in the process chamber 201 so as to penetrate a sidewall of the manifold 209. The nozzles 249a to 249c are also referred to as first to third nozzles, respectively. The nozzles 249a to 249c are made of, for example, a heat resistant material such as quartz or SiC. Gas supply pipes 232a to 232c are connected to the nozzles 249a to 249c, respectively. The nozzles 249a to 249c are different nozzles, and each of the nozzles 249a and 249c is installed adjacent to the nozzle 249b.

Mass flow controllers (MFCs) 241a to 241c, which are flow rate controllers (flow rate control parts), and valves 243a to 243c, which are opening/closing valves, are installed at the gas supply pipes 232a to 232c, respectively, sequentially from the upstream side of a gas flow. Each of gas supply pipes 232d and 232f is connected to the gas supply pipe 232a at the downstream side of the valves 243a. Each of gas supply pipes 232e and 232g is connected to the gas supply pipe 232b at the downstream side of the valve 243b. A gas supply pipe 232h is connected to the gas supply pipe 232c at the downstream side of the valve 243c. MFCs 241d to 241h and valves 243d to 243h are installed at the gas supply pipes 232d to 232h, respectively, sequentially from the upstream side of a gas flow. The gas supply pipes 232a to 232h are made of, for example, a metal material such as SUS.

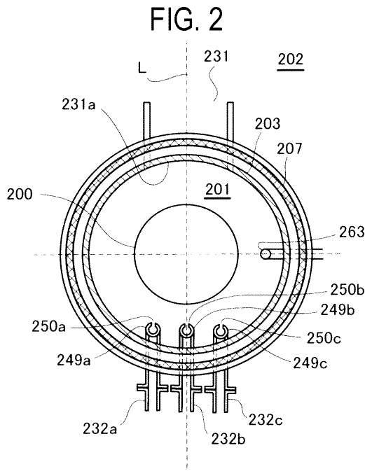

As shown in FIG. 2, each of the nozzles 249a to 249c is installed in an annular space (in a plane view) between an inner wall of the reaction tube 203 and the wafers 200 so as to extend upward from a lower side to an upper side of the inner wall of the reaction tube 203, that is, along an arrangement direction of the wafers 200. Specifically, each of the nozzles 249a to 249c is installed in a region horizontally surrounding a wafer arrangement region in which the wafers 200 are arranged at a lateral side of the wafer arrangement region, along the wafer arrangement region. In the plane view, the nozzle 249b is disposed so as to face an exhaust port 231a to be described later on a straight line with centers of the wafers 200 in the process chamber 201 interposed therebetween. The nozzles 249a and 249c are arranged so as to sandwich a straight line L passing through the nozzle 249b and a center of the exhaust port 231a from both sides along the inner wall of the reaction tube 203 (outer peripheries of the wafers 200). The straight line L is also a straight line passing through the nozzle 249b and the centers of the wafers 200. That is, it may be said that the nozzle 249c is installed on the side opposite to the nozzle 249a with the straight line L interposed therebetween. The nozzles 249a and 249c are arranged in line symmetry with the straight line L as the axis of symmetry. Gas supply holes 250a to 250c configured to supply a gas are formed on the side surfaces of the nozzles 249a to 249c, respectively. Each of the gas supply holes 250a to 250c is opened so as to oppose (face) the exhaust port 231a in the plane view, which enables a gas to be supplied toward the wafers 200. A plurality of gas supply holes 250a to 250c are formed from the lower side to the upper side of the reaction tube 203.

A modifying agent is supplied from the gas supply pipe 232a into the process chamber 201 via the MFC 241a, the valve 243a, and the nozzle 249a.

An oxidizing agent is supplied from the gas supply pipe 232b into the process chamber 201 via the MFC 241b, the valve 243b, and the nozzle 249b. The oxidizing agent is used as an altering agent.

A catalyst is supplied from the gas supply pipe 232c into the process chamber 201 via the MFC 241c, the valve 243c, and the nozzle 249c. The catalyst is used as an altering agent.

An etching agent is supplied from the gas supply pipe 232d into the process chamber 201 via the MFC 241d, the valve 243d, the gas supply pipe 232a, and the nozzle 249a.

A deactivating agent is supplied from the gas supply pipe 232e into the process chamber 201 via the MFC 241e, the valve 243e, the gas supply pipe 232b, and the nozzle 249b.

An inert gas is supplied from the gas supply pipes 232f to 232h into the process chamber 201 via the MFCs 241f to 241h, the valves 243f to 243h, the gas supply pipes 232a to 232c, and the nozzles 249a to 249c, respectively. The inert gas acts as a purge gas, a carrier gas, a dilution gas, or the like.

A modifying agent supply system mainly includes the gas supply pipe 232a, the MFC 241a, and the valve 243a. An oxidizing agent supply system mainly includes the gas supply pipe 232b, the MFC 241b, and the valve 243b. A catalyst supply system mainly includes the gas supply pipe 232c, the MFC 241c, and the valve 243c. An etching agent supply system mainly includes the gas supply pipe 232d, the MFC 241d, and the valve 243d. A deactivating agent supply system mainly includes the gas supply pipe 232e, the MFC 241e, and the valve 243e. An inert gas supply system mainly includes the gas supply pipes 232f to 232h, the MFCs 241f to 241h, and the valves 243f to 243h. Either or both of the oxidizing agent supply system and the catalyst supply system are also referred to as an altering agent supply system.

One or the entirety of the above-described various supply systems may be constituted as an integrated-type supply system 248 in which the valves 243a to 243h, the MFCs 241a to 241h, and so on are integrated. The integrated-type supply system 248 is connected to each of the gas supply pipes 232a to 232h. In addition, the integrated-type supply system 248 is configured such that operations of supplying various kinds of substances (gases) into the gas supply pipes 232a to 232h (that is, opening/closing operations of the valves 243a to 243h, flow rate regulating operations by the MFCs 241a to 241h, and the like) are controlled by a controller 121 which will be described later. The integrated-type supply system 248 is constituted as an integral-type or detachable-type integrated unit, and may be attached to or detached from the gas supply pipes 232a to 232h and the like on an integrated unit basis, so that the maintenance, replacement, extension, etc. of the integrated-type supply system 248 may be performed on an integrated unit basis.

The exhaust port 231a configured to exhaust an internal atmosphere of the process chamber 201 is installed below the sidewall of the reaction tube 203. As shown in FIG. 2, in the plane view, the exhaust port 231a is installed at a position opposing (facing) the nozzles 249a to 249c (the gas supply holes 250a to 250c) with the wafers 200 interposed therebetween. The exhaust port 231a may be installed from the lower side to the upper side of the sidewall of the reaction tube 203, that is, along the wafer arrangement region. An exhaust pipe 231 is connected to the exhaust port 231a. A vacuum pump 246 as a vacuum exhauster is connected to the exhaust pipe 231 via a pressure sensor 245, which is a pressure detector (pressure detection part) configured to detect an internal pressure of the process chamber 201, and an auto pressure controller (APC) valve 244, which is a pressure regulator (pressure adjustment part). The APC valve 244 is configured to be capable of performing or stopping a vacuum exhausting operation in the process chamber 201 by opening or closing the valve while the vacuum pump 246 is actuated, and is also configured to be capable of regulating the internal pressure of the process chamber 201 by adjusting a degree of valve opening based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219, which serves as a furnace opening lid configured to be capable of hermetically sealing a lower end opening of the manifold 209, is installed under the manifold 209. The seal cap 219 is made of, for example, a metal material such as SUS, and is formed in a disc shape. An O-ring 220b, which is a seal making contact with the lower end of the manifold 209, is installed on an upper surface of the seal cap 219. A rotator 267 configured to rotate a boat 217, which will be described later, is installed under the seal cap 219. A rotary shaft 255 of the rotator 267 is connected to the boat 217 through the seal cap 219. The rotator 267 is configured to rotate the wafers 200 by rotating the boat 217. The seal cap 219 is configured to be vertically moved up or down by a boat elevator 115 which is an elevator installed outside the reaction tube 203. The boat elevator 115 is constituted as a transfer apparatus (transfer mechanism) configured to load or unload (transfer) the wafers 200 into or out of the process chamber 201 by moving the seal cap 219 up or down.

A shutter 219s, which serves as a furnace opening lid configured to be capable of hermetically sealing a lower end opening of the manifold 209 in a state where the seal cap 219 is lowered and the boat 217 is unloaded from the process chamber 201, is installed under the manifold 209. The shutter 219s is made of, for example, a metal material such as SUS, and is formed in a disc shape. An O-ring 220c, which is a seal making contact with the lower end of the manifold 209, is installed on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC are installed in multiple stages at a lower side of the boat 217.

A temperature sensor 263 serving as a temperature detector is installed in the reaction tube 203. Based on temperature information detected by the temperature sensor 263, a state of supplying electric power to the heater 207 is regulated such that a temperature distribution in the process chamber 201 becomes a desired temperature distribution. The temperature sensor 263 is installed along the inner wall of the reaction tube 203.

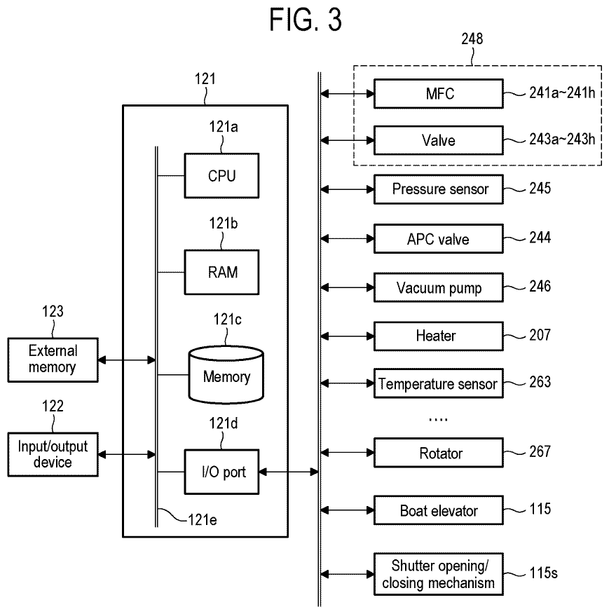

As shown in FIG. 3, a controller 121, which is a control part (control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 constituted as, e.g., a touch panel or the like, is connected to the controller 121. Further, an external memory 123 may be connected to the controller 121. Further, the processing apparatus may be configured to include one controller, or may be configured to include a plurality of controllers. That is, control to perform a processing sequence to be described later may be performed by using one controller, or may be performed by using a plurality of controllers. Further, the plurality of controllers may be constituted as a control system in which the plurality of controllers are connected to each other via a wired or wireless communication network, and the entire control system may perform control to perform the processing sequence to be described later. When the term “controller” is used in the present disclosure, it may include a plurality of controllers or a control system constituted by a plurality of controllers, as well as one controller.

The memory 121c is constituted by, for example, a flash memory, a hard disk drive (HDD), a solid state drive (SSD), or the like. A control program to control operations of a processing apparatus, a process recipe in which sequences and conditions of substrate processing to be described later are written, etc. are readably recorded and stored in the memory 121c. The process recipe functions as a program that is combined to cause, by the controller 121, the processing apparatus to execute each sequence in the substrate processing (etching process), which will be described later, to obtain an expected result. Hereinafter, the process recipe and the control program may be generally and simply referred to as a “program.” Further, the process recipe may be simply referred to as a “recipe.” When the term “program” is used herein, it may indicate a case of including the recipe, a case of including the control program, or a case of including both the recipe and the control program. The RAM 121b is constituted as a memory area (work area) in which programs or data read by the CPU 121a are temporarily stored.

The I/O port 121d is connected to the MFCs 241a to 241h, the valves 243a to 243h, the pressure sensor 245, the APC valve 244, the vacuum pump 246, the temperature sensor 263, the heater 207, the rotator 267, the boat elevator 115, the shutter opening/closing mechanism 115s, and so on.

The CPU 121a is configured to be capable of reading and executing the control program from the memory 121c. The CPU 121a is also configured to be capable of reading the recipe from the memory 121c according to an input of an operation command from the input/output device 122. The CPU 121a is configured to be capable of controlling flow rate regulating operations of various kinds of substances (gases) by the MFCs 241a to 241h, opening/closing operations of the valves 243a to 243h, an opening/closing operation of the APC valve 244, a pressure regulating operation performed by the APC valve 244 based on the pressure sensor 245, actuating and stopping operations of the vacuum pump 246, a temperature regulating operation performed by the heater 207 based on the temperature sensor 263, an operation of rotating the boat 217 and adjusting a rotation speed of the boat 217 with the rotator 267, an operation of moving the boat 217 up or down by the boat elevator 115, an opening/closing operation of the shutter 219s by the shutter opening/closing mechanism 115s, and so on, according to contents of the read recipe.

The controller 121 may be configured by installing, on the computer, the aforementioned program recorded and stored in the external memory 123. Examples of the external memory 123 may include a magnetic disk such as a HDD, an optical disc such as a CD, a magneto-optical disc such as a MO, a semiconductor memory such as a USB memory or a SSD, and the like. The memory 121c or the external memory 123 is constituted as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Further, the program may be provided to the computer by using a communication means or unit such as the Internet or a dedicated line, instead of using the external memory 123.

### (2) Processing Process

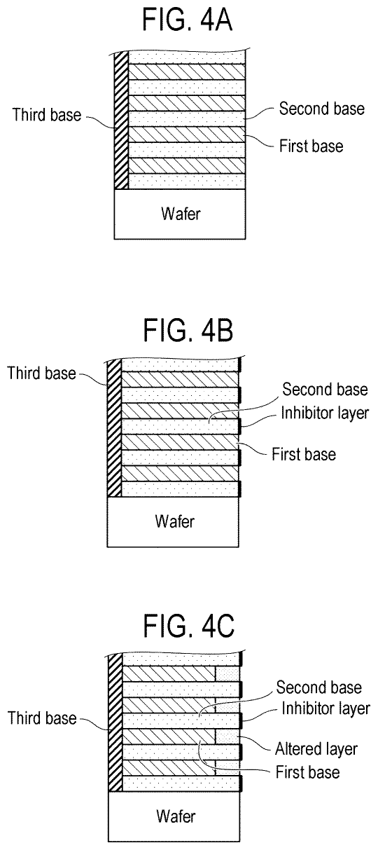

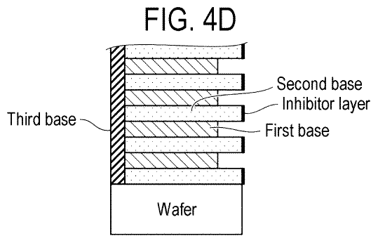

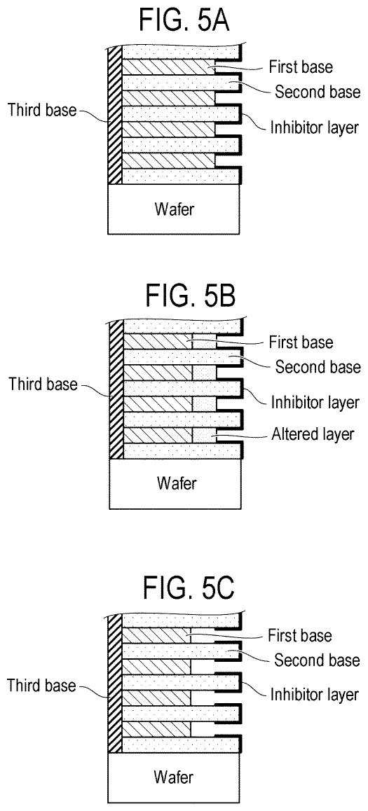

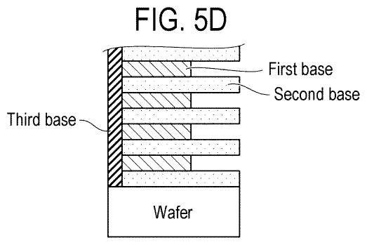

As a process (method) of manufacturing a semiconductor device using the above-described processing apparatus, an example of a method of processing a substrate (processing method), that is, a processing sequence for selectively etching a first base on a surface of a wafer 200 as a substrate among the first base and a second base on the surface of the wafer 200, will be described mainly with reference to FIGS. 4A to 4D and FIGS. 5A to 5D. In the following description, operations of the respective components constituting the processing apparatus are controlled by the controller 121. The processing apparatus is also referred to as a substrate processing apparatus, an etching processing apparatus, or an etching apparatus. The processing method is also referred to as a substrate processing method, an etching processing method, or an etching method.

A processing sequence of the embodiments of the present disclosure includes:
performing a cycle a predetermined number of times (n times, where n is an integer of 1 or 2 or more), the cycle including:
(a) step A of supplying a modifying agent to a wafer 200 including a first base and a second base on a surface of the wafer 200 to form an inhibitor layer on a surface of the second base;
(b) step B of supplying an altering agent whose a molecular structure is different from a molecular structure of the modifying agent to the wafer 200 to alter at least a portion of the first base; and
(c) step C of supplying an etching agent to the wafer 200 to etch at least a portion of an altered portion of the first base.

As a result, a predetermined amount of the first base can be etched.

In the following example, a case of further including (d) step D of performing at least one selected from the group of removal of the inhibitor layer remaining on the surface of the second base after the etching and deactivation of the inhibitor layer remaining on the surface of the second base after the etching is will be described. In step D, for example, a deactivating agent is supplied to the wafer 200. However, in a case where the inhibitor layer remaining on the surface of the second base after the etching may not be removed or deactivated, or in a case where no inhibitor layer remains on the surface of the second base after the etching, step D may be omitted.

In the present disclosure, the above-described processing sequence may be shown as follows for the sake of convenience. Note that the same notation may be used in the description of the following modifications and the like.

$$( Modifying agent \to Altering agent \to Etching agent ) \times n$$

$$( Modifying agent \to Altering agent \to Etching agent ) \times n \to Deactivating agent$$

In addition, in the following example, a case of supplying an oxidizing agent and a catalyst to the wafer 200 as altering agents in step B will be described. However, depending on process conditions, the supply of the catalyst may be omitted.

A reactivity of the modifying agent with the second base may be higher than a reactivity of the modifying agent with the first base. In addition, a reactivity of the altering agent with the first base may be higher than a reactivity of the altering agent with the inhibitor layer. In addition, the reactivity of the altering agent with the first base may be higher than a reactivity of the altering agent with the second base. In addition, a reactivity of the etching agent with the altered portion of the first base may be higher than a reactivity of the etching agent with the inhibitor layer. In addition, the reactivity of the etching agent with the altered portion of the first base may be higher than a reactivity of the etching agent with the second base.

When the term “wafer” is used in the present disclosure, it may refer to “a wafer itself” or “a stacked body of a wafer and certain layers or films formed on a surface of the wafer.” When the phrase “a surface of a wafer” is used in the present disclosure, it may refer to “a surface of a wafer itself” or “a surface of a certain layer formed on a wafer.” When the expression “a certain layer is formed on a wafer” is used in the present disclosure, it may mean that “a certain layer is formed directly on a surface of a wafer itself” or that “a certain layer is formed on a layer formed on a wafer.” When the term “substrate” is used in the present disclosure, it may be synonymous with the term “wafer.”

The term “agent” used in the present disclosure includes at least one selected from the group of a gaseous substance and a liquefied substance. The liquefied substance includes a misty substance. That is, each of a modifying agent, an altering agent (an oxidizing agent, a catalyst), an etching agent, and a deactivation agent may include a gaseous substance, a liquefied substance such as a misty substance, or both of them.

The term “layer” used in the present disclosure includes at least one selected from the group of a continuous layer and a discontinuous layer. For example, an inhibitor layer may include a continuous layer, a discontinuous layer, or both of them, as long as it is capable of generating a reaction suppressing action (an alteration suppressing action or an etching suppressing action). In addition, for example, an altered layer may include a continuous layer, a discontinuous layer, or both of them, as long as it is a layer in which at least a portion of the first base is altered.

### Wafer Charging and Boat Loading

After the boat 217 is charged with a plurality of wafers 200 (wafer charging), the shutter 219s is moved by the shutter opening/closing mechanism 115s and the lower end opening of the manifold 209 is opened (shutter opening). Thereafter, as shown in FIG. 1, the boat 217 supporting the plurality of wafers 200 is lifted up by the boat elevator 115 to be loaded into the process chamber 201 (boat loading). In this state, the seal cap 219 seals the lower end of the manifold 209 via the O-ring 220b. Thus, the wafers 200 are prepared inside the process chamber 201.

Each of the wafers 200 charged into the boat 217 includes a first base, which is an etching target, and a second base, which is a non-etching target, on the surface thereof, as shown in FIG. 4A. As shown in FIG. 4A, the first base and the second base are alternately stacked with being adjacent to each other, and each of them is adjacent to the third base. FIG. 4A shows an example in which the first bases and the second bases alternately stacked with being adjacent to each other are in contact with each other, and each of the first bases and the second bases is in contact with the third base. The first base includes a material with a low reactivity with the etching agent and cannot be directly etched by the etching agent alone, or a material that is difficult to directly etch by the etching agent alone. The first base contains, for example, silicon (Si). The first base may be, for example, an oxygen (O)-free film such as a silicon film (Si film). The second base includes a material that with a reactivity with the etching agent lower than a reactivity between the etching agent and the altered portion of the first base. The second base contains, for example, silicon (Si) and oxygen (O). The second base may further contains carbon (C). The second base may be, for example, an oxygen (O)-containing film such as a silicon oxide carbide film (SiOC film). As described above, the first base and the second base are different from each other in material, component, composition, and molecular structure. The third base may be made of, for example, a material different from that of the first base, and may be made of, for example, the same material as the second base or a material different from that of the second base.

The first base and the second base may be, for example, a film (CVD film) formed by chemical vapor deposition (CVD) method. Examples of the CVD method may include a thermal CVD method, a plasma CVD method, and a photo CVD method. A processing temperature when forming a film may be, for example, 350 to 800 degrees C., specifically 450 to 700 degrees C.

### Pressure Regulation and Temperature Regulation

After the boat loading is completed, an inside of the process chamber 201, that is, a space where the wafers 200 are placed, is vacuum-exhausted (decompression-exhausted) by the vacuum pump 246 to reach a desired pressure (degree of vacuum). In this operation, the internal pressure of the process chamber 201 is measured by the pressure sensor 245, and the APC valve 244 is feedback-controlled based on the measured pressure information. Further, the wafers 200 in the process chamber 201 are heated by the heater 207 so as to reach a desired processing temperature. At this time, a state of supplying electric power to the heater 207 is feedback-controlled based on the temperature information detected by the temperature sensor 263 so that a temperature distribution in the process chamber 201 becomes a desired temperature distribution. Further, the rotation of the wafers 200 by the rotator 267 is started. The exhaust of the inside of the process chamber 201 and the heating and rotation of the wafers 200 are continuously performed at least until the processing on the wafers 200 is completed.

### Step A

After that, a modifying agent (modifying gas) is supplied to the wafer 200 to form an inhibitor layer on the surface of the second base.

Specifically, the valve 243a is opened to allow the modifying agent to flow through the gas supply pipe 232a. A flow rate of the modifying agent is regulated by the MFC 241a, and the modifying agent is supplied into the process chamber 201 via the nozzle 249a and is exhausted through the exhaust port 231a. In this operation, the modifying agent is supplied to the wafer 200 from the side of the wafer 200 (supply of modifying agent). At this time, the valves 243f to 243h may be opened to allow an inert gas to be supplied into the process chamber 201 via the nozzles 249a to 249c, respectively.

By supplying the modifying agent to the wafer 200 under process conditions to be described below, an inhibitor molecule, which is at least a portion of a molecular structure of a molecule constituting the modifying agent, is selectively chemically adsorbed on the surface (exposed surface) of the second base of the wafer 200, such that the inhibitor layer may be selectively formed on the surface of the second base, as shown in FIG. 4B. The inhibitor layer can generate an action of suppressing or inhibiting the reaction of the second base with the altering agent or the reaction of the second base with the etching agent, so it can also be said to be a reaction suppression layer (an alteration suppression layer or an etching suppression layer) or a reaction inhibition layer (an alteration inhibition layer or and etching inhibition layer). The inhibitor molecule may also be said to be a reaction suppression molecule or a reaction inhibition molecule. The inhibitor layer formed in this step contains at least a portion of the molecular structure of the molecule constituting the modifying agent, which are residues derived from the modifying agent. The inhibitor layer prevents the altering agent from coming into contact with the surface of the second base in step B, thereby suppressing or inhibiting the alteration of the second base. The inhibitor layer is a layer that covers the surface of the second base, and may prevent the etching agent from coming into contact with the surface of the second base in step C, thereby suppressing or inhibiting the etching of the second base. In other words, the inhibitor layer may be said to be a protective layer that protects the surface (exposed surface) of the second base.

At least a portion of the molecular structure of the molecule constituting the modifying agent, i.e., the inhibitor molecule, may be, for example, a trialkylsilyl group such as a trimethylsilyl group (—SiMe₃) or a triethylsilyl group (—SiEt₃). The trialkylsilyl group contains an alkyl group, which is a type of hydrocarbon group. When the inhibitor molecule contains these, Si of the trimethylsilyl group or the triethylsilyl group is adsorbed on an adsorption site on the surface of the second base of the wafer 200. When the second base is, for example, a SiOC film, the surface of the second base contains an OH termination (OH group) as the adsorption site, and Si of the trimethylsilyl group or the triethylsilyl group is bonded to O of the OH termination (OH group) on the surface of the second base, and the surface of the second base is terminated by an alkyl group such as a methyl group or an ethyl group. The hydrocarbon group, typified by an alkyl group (alkylsilyl group) such as a methyl group (trimethylsilyl group) or an ethyl group (triethylsilyl group), which terminates the surface of the second base, may constitute the inhibitor layer to prevent the altering agent from being in contact with the surface of the second base in step B, thereby suppressing or inhibiting the alteration of the second base, i.e., progression of alteration reaction of the second base. In addition, the hydrocarbon group terminating the surface of the second base may prevent the etching agent from being in contact with the surface of the second base in step C, thereby suppressing or inhibiting the etching of the second base, i.e., progression of etching reaction of the second base.

When the inhibitor molecule adsorbed on the adsorption site on the surface of the second base is a trialkylsilyl group such as a trimethylsilyl group (—SiMe₃) or a triethylsilyl group (—SiEt₃), the inhibitor molecule contains an alkyl group (alkylsilyl group), and the inhibitor layer contains an alkyl group (alkylsilyl group) termination. When the inhibitor layer contains a hydrocarbon group termination such as an alkyl group (alkylsilyl group) termination, an appropriate reaction inhibition effect (an alteration inhibition effect and an etching inhibition effect) may be obtained. Further, the alkyl group (alkylsilyl group) termination and the hydrocarbon group termination are also called an alkyl (alkylsilyl) termination and a hydrocarbon termination, respectively.

Note that, in this step, at least the portion of the molecular structure of the molecule constituting the modifying agent may be adsorbed on a portion of the surface of the first base of the wafer 200, but an amount of adsorption thereof is very small, and an amount of adsorption on the surface of the second base of the wafer 200 is overwhelmingly large. Such selective (preferential) adsorption is possible because the reactivity of the modifying agent with the second base is higher than the reactivity of the modifying agent with the first base. For example, as in the case where the second base is a SiOC film and the first base is a Si film, the surface of the second base is OH-terminated over its entire region, while many regions of the surface of the first base are not OH-terminated. This is also because the process conditions in this step are such that the modifying agent does not undergo gas-phase decomposition in the process chamber 201. As a result, in this step, at least a portion of the molecular structure of the molecule constituting the modifying agent is not multi-deposited on the surface of the first base and the surface of the second base, and at least a portion of the molecular structure of the molecule constituting the modifying agent is selectively adsorbed on the surface of the second base among the surface of the first base and the surface of the second base, such that the surface of the second base is selectively terminated with at least the portion of the molecular structure of the molecule constituting the modifying agent.

Process conditions when the modifying agent is supplied in step A are exemplified as follows:
Processing temperature: room temperature (25 degrees C.) to 500 degrees C., specifically room temperature to 250 degrees C.
Processing pressure: 5 to 2,000 Pa, specifically 10 to 1,000 Pa
Supply flow rate of modifying agent: 0.001 to 3 slm, specifically 0.001 to 0.5 slm
Supply time of modifying agent: 1 to 300 seconds, specifically 5 to 120 seconds
Supply flow rate of inert gas (for each gas supply pipe): 0 to 20 slm

In the present disclosure, notation of a numerical range such as “25 to 500 degrees C.” means that a lower limit value and an upper limit value are included in the range. Therefore, for example, “25 to 500 degrees C.” means “25 degrees C. or higher and 500 degrees C. or lower.” The same applies to other numerical ranges. In the present disclosure, a processing temperature means a temperature of the wafer 200 or an internal temperature of the process chamber 201, and a processing pressure means an internal pressure of the process chamber 201. Further, a processing time means a time during which a process is continued. Further, when 0 slm is included in a supply flow rate, it means a case where no substance (gas) is supplied. The same applies to the following description.

After selectively forming the inhibitor layer on the surface of the second base of the wafer 200, the valve 243a is closed to stop the supply of the modifying agent into the process chamber 201. Then, the inside of the process chamber 201 is vacuum-exhausted to remove a gaseous substance and the like remaining in the process chamber 201 from the process chamber 201. At this time, the valves 243f to 243h are opened to allow an inert gas to be supplied into the process chamber 201 via the nozzles 249a to 249c, respectively. The inert gas supplied from the nozzles 249a to 249c acts as a purge gas, whereby the inside of the process chamber 201 is purged (purging).

Process conditions when purging is performed in step A are exemplified as follows:
Processing pressure: 1 to 30 Pa
Processing time: 1 to 120 seconds, specifically 1 to 60 seconds
Supply flow rate of inert gas (for each gas supply pipe): 0.5 to 20 slm

The processing temperature when purging is performed in this step may be the same as the processing temperature when the modifying agent is supplied.

The modifying agent may include an organic substance. In addition, the modifying agent may contain at least one selected from the group of an alkyl group and an amino group. As the modifying agent, for example, a compound with a structure in which an amino group is directly bonded to Si, a compound with a structure in which an alkyl group is directly bonded to Si, or a compound with a structure in which an amino group and an alkyl group are directly bonded to Si can be used. The amino group in these compounds may be a substituted amino group substituted with an alkyl group such as a methyl group or an ethyl group.

Examples of the modifying agent may include bis(dipropylamino)dimethylsilane ([(C₃H₇)₂N]₂Si(CH₃)₂), bis(dipropylamino)diethylsilane ([(C₃H₇)₂N]₂Si(C₂H₅)₂), bis(dimethylamino)dimethylsilane ([(CH₃)₂N]₂Si(CH₃)₂), bis(diethylamino)diethylsilane ([(C₂H₅)₂N]₂Si(C₂H₅)₂), bis(dimethylamino)diethylsilane ([(CH₃)₂N]₂Si(C₂H₅)₂), bis(diethylamino)dimethylsilane ([(C₂H₅)₂N]₂Si(CH₃)₂), bis(dimethylamino)silane ([(CH₃)₂N]₂SiH₂), bis(diethylamino)silane ([(C₂H₅)₂N]₂SiH₂), bis(dimethylaminodimethylsilyl)ethane ([(CH₃)₂N(CH₃)₂Si]₂C₂H₆), bis(dipropylamino)silane ([(C₃H₇)₂N]₂SiH₂), bis(dibutylamino)silane ([(C₄H₉)₂N]₂SiH₂), (dimethylsilyl)diamine ((CH₃)₂Si(NH₂)₂), (diethylsilyl)diamine ((C₂H₅)₂Si(NH₂)₂), (dipropylsilyl)diamine ((C₃H₇)₂Si(NH₂)₂), bis(dimethylaminodimethylsilyl)methane ([(CH₃)₂N(CH₃)₂Si]₂CH₂), bis(dimethylamino)tetramethyldisilane ([(CH₃)₂N]₂(CH₃)₄Si₂), etc. One or more of these may be used as the modifying agent.

In addition, examples of the modifying agent may include (dipropylamino)trimethylsilane ((C₃H₇)₂NSi(CH₃)₃), (dibutylamino)trimethylsilane ((C₄H₉)₂NSi(CH₃)₃), (dimethylamino)trimethylsilane ((CH₃)₂NSi(CH₃)₃), (diethylamino)triethylsilane ((C₂H₅)₂NSi(C₂H₅)₃), (dimethylamino)triethylsilane ((CH₃)₂NSi(C₂H₅)₃), (diethylamino)trimethylsilane ((C₂H₅)₂NSi(CH₃)₃), (trimethylsilyl)amine ((CH₃)₃SiNH₂), (triethylsilyl)amine ((C₂H₅)₃SiNH₂), (dimethylamino)silane ((CH₃)₂NSiH₃), (diethylamino)silane ((C₂H₅)₂NSiH₃), (dipropylamino)silane ((C₃H₇)₂NSiH₃), (dibutylamino)silane ((C₄H₉)₂NSiH₃), etc. One or more of these can be used as the modifying agent.

As the inert gas, a nitrogen (N₂) gas and rare gases such as an argon (Ar) gas, a helium (He) gas, a neon (Ne) gas, and a xenon (Xe) gas can be used. One or more of these gases may be used as the inert gas. The same applies to each step to be described below.

### Step B

After step A is completed, an altering agent (altering gas) with a molecular structure different from that of the modifying agent is supplied to the wafer 200, i.e., the wafer 200 after the inhibitor layer is formed on the surface of the second base, to modify at least a portion of the first base. Herein, an example in which an oxidizing agent (oxidizing gas) and a catalyst (catalyst gas) are supplied as the altering agent will be described.

Specifically, the valves 243b and 243c are opened to allow the oxidizing agent and the catalyst to flow through the gas supply pipes 232b and 232c, respectively. Flow rates of the oxidizing agent and the catalyst are regulated by the MFCs 241b and 241c, respectively, and the oxidizing agent and the catalyst are supplied into the process chamber 201 via the nozzles 249b and 249c, are mixed in the process chamber 201, and are exhausted via the exhaust port 231a. In this operation, the oxidizing agent and the catalyst are supplied to the wafer 200 from the side of the wafer 200 (supply of oxidizing agent+catalyst). At this time, the valves 243f to 243h may be opened to allow an inert gas to be supplied into the process chamber 201 via the nozzles 249a to 249c, respectively.

By supplying the oxidizing agent and the catalyst to the wafer 200 under process conditions to be described below, it is possible to selectively alter at least a portion of the first base while suppressing the alteration of the second base. That is, it is possible to selectively oxidize at least a portion of the first base while suppressing the oxidation of the second base. As a result, as shown in FIG. 4C, an altered layer formed by alteration of the first base, that is, an oxide layer formed by oxidation of the first base, is formed on at least a portion of a surface side (an exposed surface side) of the first base. In a case where the first base is, for example, a Si film, the altered layer, that is, the oxide layer, is a layer containing at least Si and O. In this step, by supplying the catalyst together with the oxidizing agent, it is possible to proceed with the above-described oxidation reaction under a low temperature condition as described below.

In this step, the reason why at least a portion of the first base among the first base and the second base can be selectively (preferentially) altered is that the reactivity of the altering agent with the first base is higher than the reactivity of the altering agent with the inhibitor layer. This is also possible because the reactivity of the altering agent with the first base is higher than the reactivity of the altering agent with the second base. As a result, in this step, the reaction between the altering agent and the first base proceeds selectively, and at least a portion of the first base is selectively altered.

Process conditions when the altering agent (oxidizing agent and catalyst) is supplied in step B are exemplified as follows:
Processing temperature: room temperature (25 degrees C.) to 500 degrees C., specifically room temperature to 200 degrees C., more specifically room temperature to 150 degrees C.
Processing pressure: 1 to 13,332 Pa, specifically 133 to 1,333 Pa
Supply flow rate of oxidizing agent: 0.001 to 5 slm, specifically 0.001 to 2 slm
Supply flow rate of catalyst: 0 to 2 slm, specifically 0.001 to 2 slm
Supply flow rate of inert gas (for each gas supply pipe): 0 to 20 slm
Supply time of each substance: 1 to 300 seconds, specifically 5 to 120 seconds

After at least the portion of the first base is altered, the valves 243b and 243c are closed to stop the supply of the oxidizing agent and catalyst into the process chamber 201, respectively. Then, a gaseous substance and the like remaining in the process chamber 201 are removed from the process chamber 201 (purging) according to the same processing procedure and process conditions as those of the purging in step A. Note that the processing temperature when purging is performed in this step may be the same as the processing temperature when the altering agent is supplied.

As the oxidizing agent for the altering agent, a hydrogen (H)- and oxygen (O)-containing gas, which is an oxidizing gas, may be used. As the H- and O-containing gas, for example, a hydrogen peroxide (H₂O₂) gas, water vapor (H₂O gas), hydrogen (H₂) gas+oxygen (O₂) gas, H₂ gas+ozone (O₃) gas, and the like may be used. That is, as the H- and O-containing gas, H-containing gas+O-containing gas (reducing gas+oxidizing gas) may also be used. In this case, as the H-containing gas, i.e., the reducing gas, a deuterium (D₂) gas may also be used instead of the H₂ gas. In addition, as the oxidizing agent, an O-containing gas, a N- and an O-containing gas, and a C- and O-containing gas, such as an O₂ gas, a nitrous oxide (N₂O) gas, a nitric oxide (NO) gas, a nitrogen dioxide (NO₂) gas, a carbon dioxide (CO₂) gas, and a carbon monoxide (CO) gas may be used. Like these, as the altering agent, for example, a H- and O-containing substance, a D- and O-containing substance, an O-containing substance, a N- and O-containing substance, and a C- and O-containing substance may be used. As the oxidizing agent for the altering agent, one or more of these substances can be used.

Note that, in the present disclosure, description of two gases such as “H₂ gas+O₂ gas” together means a mixture gas of H₂ gas and O₂ gas. When supplying the mixture gas, the two gases may be mixed (pre-mixed) in a supply pipe and then supplied into the process chamber 201, or the two gases may be supplied separately from different supply pipes into the process chamber 201 and then mixed (post-mixed) in the process chamber 201.

As the catalyst for the altering agent, for example, an amine-based gas (amine-based substance) containing carbon (C), nitrogen (N), and hydrogen (H) may be used. As the amine-based gas, a cyclic amine-based gas (cyclic amine-based substance) or a chain amine-based gas (chain amine-based substance) may be used. As the catalyst, for example, cyclic amines such as aminopyridine (C₅H₆N₂), picoline (C₆H₇N), lutidine (C₇H₉N), pyrimidine (C₄H₄N₂), pyridine (C₅H₅N), quinoline (C₉H₇N), piperazine (C₄H₁₀N₂), piperidine (C₅H₁₁N), and aniline (C₆H₇N) may be used. In addition, as the catalyst, for example, chain amines such as triethylamine ((C₂H₅)₃N), diethylamine ((C₂H₅)₂NH), monoethylamine ((C₂H₅)NH₂), trimethylamine ((CH₃)₃N), dimethylamine ((CH₃)₂NH), and monomethylamine ((CH₃)NH₂) may be used. In addition, as the catalyst, ammonia (NH₃) may also be used. One or more of these may be used as the catalyst for the altering agent. As described above, depending on the process conditions, the supply of the catalyst may be omitted.

The altered layer formed by alteration of the first base on at least the portion of the surface side of the first base described above may generate a specific substance that reacts with the etching agent but does not contribute to the etching by itself when it is etched in step C. In step C, when etching is started, as at least a portion of the altered layer is etched, at least a portion of the remaining altered layer can be etched by using a mixture of the specific substance generated from the altered layer and the etching agent. The specific substance generated from the altered layer can promote and accelerate the etching of the remaining altered layer by reacting with the etching agent. In other words, the altered layer may be said to be an etching promotion layer for the altered layer itself.

For example, by using the above-mentioned oxidizing agent and catalyst as the altering agent, an altered layer containing H and O may be formed on at least a portion of the surface side of the first base. H and O in the altered layer may be contained in the altered layer as a compound containing H and O. That is, the altered layer may contain a compound containing H and O. The altered layer containing H and O may contain, for example, H₂O as a compound containing H and O. That is, the altered layer may contain H and O, specifically a compound containing H and O, and more specifically H2O. When the altered layer contains H and O, specifically H₂O, it is possible to efficiently generate a specific substance that reacts with the etching agent but does not contribute to etching by itself when etching the altered layer in step C.

When the altered layer contains H₂O as a compound containing H and O as described above, H₂O molecule contained in the altered layer are held in the altered layer, for example, by hydrogen bonds with other components (molecules) in the altered layer. Therefore, it is believed that when the altered layer in which the H₂O molecules are held is etched, the above-mentioned hydrogen bonds are broken, and the H₂O molecules become, for example, a gas and are desorbed and released from the altered layer. In this way, H₂O contained in the altered layer is generated as a specific substance from the altered layer when the altered layer is etched in step C. In other words, when the altered layer containing H₂O is etched, H₂O is generated as a specific substance. Note that the H₂O molecules in the altered layer may seep out as a liquid on the surface of the altered layer when the altered layer is etched or in other situations.

In this step, the processing time when forming the altered layer is adjusted to obtain an altered layer with a desired thickness. Then, an amount of etching of the first base in step C can be controlled by a thickness of the altered layer formed in this step. This is because the first base includes a substance that has a low reactivity with the etching agent and cannot be directly etched by the etching agent alone or is difficult to directly etch by the etching agent alone, whereas the altered layer includes a substance that has a high reactivity with the etching agent and can be easily etched by the etching agent. In this way, the reactivity between the etching agent and the altered layer is much higher than the reactivity between the etching agent and the first base, thereby making it possible to control the amount of etching of the first base by the thickness of the altered layer. As a result, it becomes possible to improve controllability and uniformity of the amount of etching of the first base.

### Step C

After step B is completed, an etching agent (etching gas) is supplied to the wafer 200, i.e., the wafer 200 after at least the portion of the first base is altered, to etch the altered portion of the first base, i.e., at least a portion of the altered layer. As described above, in this step, when etching the altered layer, a specific substance that reacts with the etching agent but does not contribute to etching by itself is generated, and the altered layer can be etched by using a mixture of the specific substance and the etching agent. A case where the specific substance is generated during etching to promote the etching reaction will be described below.

Specifically, the valve 243d is opened to allow the etching agent to flow through the gas supply pipe 232d. A flow rate of the etching agent is regulated by the MFC 241d, and the etching agent is supplied into the process chamber 201 via the gas supply pipe 232a and the nozzle 249a and is exhausted via the exhaust port 231a. In this operation, the etching agent is supplied to the wafer 200 from the side of the wafer 200 (supply of etching agent). At this time, the valves 243f to 243h may be opened to allow an inert gas to be supplied into the process chamber 201 via the nozzles 249a to 249c, respectively.

By supplying the etching agent to the wafer 200 under process conditions to be described below, it is possible to selectively etch at least a portion of the altered layer formed on the surface side of the first base while suppressing the etching of the second base. At this time, when the etching of the altered layer is started, a specific substance is released from the altered layer, for example as a gas, and the released specific substance is mixed with the etching agent. In the mixture of the specific substance and the etching agent obtained in this manner, the specific substance reacts with the etching agent to generate an activated etching agent, such that etching of the remaining altered layer proceeds. By continuing the etching by the mixture of the specific substance and the etching agent, at least a portion of the altered portion of the first base is etched, as shown in FIG. 4D. FIG. 4D shows an example in which the entirety of the altered portion of the first base, that is, the entirety of the altered layer, is etched.

The specific substance is a substance that does not contribute to etching by itself, but can promote etching by reacting with the etching agent. That is, the specific substance can be said to be a substance that promotes etching by reacting with the etching agent, and can also be said to be a substance that activates the etching agent. Further, the specific substance may be a gas released from the altered layer, or it may include a liquid. For example, when the specific substance starts seeping out as a liquid on the surface of the altered layer when the altered layer is etched, by using a mixture of the specific substance in liquid form and the etching agent, it is possible to efficiently and effectively proceed with etching of at least a portion of the altered layer. In addition, in this case, it is also possible to promptly start etching of at least a portion of the altered layer.

In this step, the specific substance generated when etching the altered layer may contain H and O, specifically H₂O. When the specific substance contains H and O, specifically H₂O, the etching agent can be efficiently activated, which makes it possible to further promote the etching of the altered layer. As a result, it is possible to more stably perform the etching of the altered layer.

Further, in this step, the reason why at least a portion of the altered portion of the first base can be selectively (preferentially) etched is that the reactivity of the etching agent with the altered portion of the first base is higher than at least one selected from the group of the reactivity of the etching agent with the inhibitor layer and the reactivity of the etching agent with the second base.

When the reactivity of the etching agent with the altered portion of the first base is higher than the reactivity of the etching agent with the inhibitor layer, it is possible to selectively etch the altered layer while suppressing etching of the inhibitor layer. In this case, since the etching of the inhibitor layer can be suppressed, the surface of the second base can be kept protected by the inhibitor layer, and as a result, it is possible to suppress etching of the second base.

When the reactivity of the etching agent with the altered portion of the first base is higher than the reactivity of the etching agent with the second base, it is possible to selectively etch the altered layer while suppressing etching of the second base. In this case, even in a case where at least a portion of the inhibitor layer is etched, a portion of the second base that was covered by the inhibitor layer is exposed, and the exposed surface is exposed to the etching agent, the etching of the second base can be suppressed. In addition, even in a case where a portion of the second base that was in contact with the altered layer is exposed when the altered layer is etched, and the exposed surface is exposed to the etching agent, the etching of the second base can be suppressed. Like these, in a case where the reactivity of the etching agent with the altered portion of the first base is higher than the reactivity of the etching agent with the second base, it is possible to suppress the etching of the second base even when the surface of the second base is exposed and the exposed surface is exposed to the etching agent.

In addition, in this step, the reason why at least a portion of the altered portion of the first base can be selectively (preferentially) etched is that the reactivity of the etching agent with the altered portion of the first base is much higher than the reactivity of the etching agent with an unaltered portion (non-altered portion) of the first base. As a result, it is possible to selectively etch the altered layer of the first base while suppressing etching of the non-altered portion of the first base.

Process conditions when the etching agent is supplied in step C are exemplified as follows:
Processing temperature: room temperature (25 degrees C.) to 300 degrees C., specifically room temperature to 200 degrees C.
Processing pressure: 133 to 13,332 Pa, specifically 1 to 1,333 Pa
Supply flow rate of etching agent: 0.001 to 2 slm
Supply time of etching agent: 1 to 300 seconds, specifically 5 to 120 seconds
Supply flow rate of inert gas (for each gas supply pipe): 0 to 20 slm

After the etching of at least the portion of the altered portion of the first base is completed, the valve 243d is closed to stop the supply of the etching agent into the process chamber 201. Then, a gaseous substance and the like remaining in the process chamber 201 are removed from the process chamber 201 (purging) according to the same processing procedure and process conditions as those for purging in step A. Further, the processing temperature when purging in this step may be the same as the processing temperature when supplying the etching agent.

Further, the processing temperature in step C may also be the same as the processing temperature in step A and the processing temperature in step B. In that case, the time for change the processing temperature can be reduced, which makes it possible to improve a throughput of the substrate processing.

A fluorine-based substance, for example, a fluorine (F)-containing gas, may be used as the etching agent. As the F-containing gas, for example, a Cl- and F-containing gas, a N- and F-containing gas, a H- and F-containing gas, etc., such as a chlorine trifluoride (ClF₃) gas, a chlorine fluoride (ClF) gas, a nitrogen fluoride (NF₃) gas, a hydrogen fluoride (HF) gas, or a fluorine (F₂) gas may be used. Like these, the etching agent may be, for example, a Cl- and F-containing substance, a N- and F-containing substance, a H- and F-containing substance, a F-containing substance, etc. That is, the etching agent may be, for example, an interhalogen compound, nitrogen halide, hydrogen halide, a halogen element, etc. One or more of these may be used as the etching agent.

In addition, the etching agent may be a gas obtained by adding ammonia (NH₃) gas, a H₂ gas, a H₂O gas, an isopropyl alcohol ((CH₃)₂CHOH) gas, a methanol (CH₃OH) gas, or a mixture of these gases to the F-containing gas. Further, in a case where a solid by-product (complex, etc.) is generated by adding at least one of these gases to the F-containing gas, a step of sublimating the solid by-product may be added appropriately, for example, a heat treatment (annealing) step. In this case, the heat treatment step is performed at a temperature equal to or higher than the processing temperature when the etching agent is supplied, specifically at a temperature higher than the processing temperature when the etching agent is supplied, thereby making it possible to efficiently sublimate the solid by-product.

In a case where the etching agent is a F-containing substance, it is possible to efficiently generate a specific substance when etching the altered layer. In addition, in a case where the etching agent is a H- and F-containing substance, a specific substance may be generated efficiently when etching the altered layer, a specific substance may be generated by a chemical reaction between the etching agent and the altered layer during etching. Further, the above-described altered layer may contain H and O, may contain H₂O, may be an oxide layer, or may be an oxide layer containing H₂O. For example, in a case where the etching agent is a H- and F-containing substance, H₂O as a specific substance may be generated efficiently by desorption from the altered layer when etching the altered layer that is an oxide layer containing H₂O, and H₂O as a specific substance may be generated by a chemical reaction between the etching agent and the altered layer during etching.

### Performing Predetermined Number of Times

By performing a cycle a predetermined number of times (n times, where n is an integer of 1 or 2 or more), the cycle including the above-described steps A, B, and C, i.e., the cycle in which the steps are performed non-simultaneously in this order, a predetermined amount of the first base to be etched may be etched. The above-described cycle may be performed a plurality of times. That is, a thickness of the first base etched per cycle may be made to be thinner than a desired etching thickness (predetermined amount) of the first base, and the above-described cycle may be performed a plurality of times until an etching thickness of the first base reaches the desired etching thickness (depth). It is also possible to etch the entire first base by performing the above-described cycle a plurality of times.

Further, when the altered layer is etched in step C, a portion of the second base may be exposed, as shown in FIG. 4D. For example, when the altered layer is etched, a portion of the second base that was in contact with the etched altered layer or a portion of the second base from which the inhibitor layer was removed may be exposed. Even in this case, by performing step A in the next cycle, as shown in FIG. 5A, an inhibitor layer may be formed on the exposed portion of the second base, such that the surface (exposed surface or exposed portion) of the second base may be protected. For example, a new inhibitor layer may be formed on the exposed portion of the second base that was in contact with the etched altered layer, and an inhibitor layer may be re-formed on the exposed portion of the second base from which the inhibitor layer was removed, thereby repairing and reinforcing the inhibitor layer. As a result, when step B is performed thereafter, as shown in FIG. 5B, it is possible to selectively alter at least a portion of the first base while suppressing the alteration of the second base. In addition, when step C is performed thereafter, as shown in FIG. 5C, it is possible to selectively etch the altered layer while suppressing the etching of the second base. That is, in at least one subsequent cycle after a first cycle, the same reaction as in the first cycle may be caused to occur in each step, and the same reaction as in the first cycle may be allowed to proceed.

### Step D

After the etching of the first base is completed by the predetermined amount, a deactivating agent (deactivating gas) is supplied to the wafer 200 to perform at least one selected from the group of removal of the inhibitor layer remaining on the surface of the second base after the etching and deactivation of the inhibitor layer remaining on the surface of the second base after the etching.

Specifically, the valve 243e is opened to allow the deactivating agent to flow through the gas supply pipe 232e. A flow rate of the deactivating agent is regulated by the MFC 241e, and the deactivating agent is supplied into the process chamber 201 via the gas supply pipe 232b and the nozzle 249b and is exhausted via the exhaust port 231a. In this operation, the deactivating agent is supplied to the wafer 200 from the side of the wafer 200 (supply of deactivating agent). At this time, the valves 243f to 243h may be opened to allow an inert gas to be supplied into the process chamber 201 via the nozzles 249a to 249c, respectively.

By supplying the deactivating agent to the wafer 200 under process conditions to be described below, as shown in FIG. 5D, it is possible to perform at least one selected from the group of removal of the inhibitor layer remaining on the surface of the second base after etching a predetermined amount of the first base and deactivation of the inhibitor layer remaining on the surface of the second base after etching a predetermined amount of the first base. The removal of the inhibitor layer means that the inhibitor molecules as reaction suppression molecules or reaction inhibition molecules are detached from the surface of the second base, and the inhibitor layer as a reaction suppression layer or a reaction inhibition layer disappears from the surface of the second base. The deactivation of the inhibitor layer means that a function of the inhibitor molecules contained in the inhibitor layer as reaction suppression molecules or reaction inhibition molecules is inactivated due to a change in its molecular structure or atomic arrangement structure, etc., and the inhibitor layer formed on the surface of the second base loses its function as the reaction suppression layer or the reaction inhibition layer. FIG. 5D shows an example in which the inhibitor layer remaining on the surface of the second base is removed.

Process conditions when the deactivating agent is supplied in step D are exemplified as follows:
Processing temperature: 200 to 1,000 degrees C., specifically 400 to 700 degrees C.
Processing pressure: 1 to 120,000 Pa
Processing time: 1 to 18,000 seconds
Supply flow rate of deactivating agent: 0 to 50 slm
Supply flow rate of inert gas (for each gas supply pipe): 0 to 20 slm
RF power: 0 to 10,000 W

The RF power is a power applied to generate plasma when performing plasma processing in which the deactivating agent is used. In addition, the supply flow rate of the deactivating agent is 0 slm, it means a case where no deactivating agent is supplied. In other words, at least one selected from the group of removal of the inhibitor layer remaining on the surface of the second base and deactivation of the inhibitor layer remaining on the surface of the second base may be performed without supplying the deactivating agent, for example, by using thermal energy by heating.

After at least one selected from the group of removal of the inhibitor layer remaining on the surface of the second base and deactivation of the inhibitor layer remaining on the surface of the second base is performed, the valve 243e is closed to stop the supply of the deactivating agent into the process chamber 201. Then, a gaseous substance and the like remaining in the process chamber 201 are removed from the process chamber 201 (purging) according to the same processing procedure and process conditions as those for purging in step A. The processing temperature when purging in this step may be the same as the processing temperature when supplying the deactivating agent.

As the deactivating agent, the above-mentioned various oxidizing agents, reactive gases such as a NH₃ gas, a diazene (N₂H₂) gas, a hydrazine (N₂H₄) gas, a H₂ gas, and a D₂ gas, inert gases such as a He gas, an Ar gas, and a N₂ gas, and mixtures of these gases may be used. As the deactivating agent, these gases may be excited into a plasma state and supplied, or may be excited by heat and supplied. One or more of these gases may be used as the deactivating agent.

Further, as described above, in a case where the inhibitor layer remaining on the surface of the second base after the etching may not be removed or deactivated, or in a case where no inhibitor layer remains on the surface of the second base after the etching, step D may be omitted.

### After-Purge and Returning to Atmospheric Pressure

After step D is completed, an inert gas is supplied as a purge gas into the process chamber 201 from each of the nozzles 249a to 249c and is exhausted via the exhaust port 231a. Thus, the interior of the process chamber 201 is purged and a gas, reaction by-products, and the like remaining in the process chamber 201 are removed from the inside of the process chamber 201 (after-purge). After that, the internal atmosphere of the process chamber 201 is substituted with an inert gas (inert gas substitution) and the internal pressure of the process chamber 201 is returned to the atmospheric pressure (returning to atmospheric pressure).

### Boat Unloading and Wafer Discharging

After that, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter closing). The processed wafers 200 are unloaded from the reaction tube 203 and are then discharged from the boat 217 (wafer discharging).

At least steps A, B, and C are performed in the same process chamber (in-situ). As a result, after forming the inhibitor layer on the surface of the first base of the wafer 200 by step A, steps B and C may be performed without exposing the wafer 200 to the atmosphere, i.e., while keeping the surface of the wafer 200 clean, and etching of the first base, which is the etching target, may be performed appropriately.

### (3) Effects of the Embodiments

According to the embodiments of the present disclosure, one or more effects set forth below can be achieved.

By performing a cycle a predetermined number of times, the cycle including steps A, B, and C, it is possible to selectively alter and etch at least a portion of the first base, which is the etching target, while suppressing alteration and etching of the second base, which is the non-etching target, among the first and second bases. In addition, it is possible to promote the etching of the first base, which is the etching target, and to stably etch the first base. In addition, it is possible to etch the first base, which is the etching target, with good controllability, and also to improve controllability and uniformity of the amount of etching. This allows depth etching, i.e., etching in a direction perpendicular to the surface of the wafer, and lateral etching, i.e., etching in a direction other than the direction perpendicular to the surface of the wafer, for example, etching in a direction parallel to the surface of the wafer, to be performed with high controllability and uniformity. Further, even in a case where the reactivity of the etching agent with the first base is low and the first base cannot be directly etched by the etching agent, it is possible to etch the first base. Further, by performing the cycle, which includes performing steps A, B, and C in this order, it is possible to more effectively produce these effects.

In this case, the reactivity of the modifying agent with the second base may be higher than the reactivity of the modifying agent with the first base. This makes it possible to effectively form a selective inhibitor layer on the surface of the second base, which is the non-etching target.

In addition, in this case, the reactivity of the altering agent with the first base may be higher than the reactivity of the altering agent with the inhibitor layer. In addition, in this case, the reactivity of the altering agent with the first base may be higher than the reactivity of the altering agent with the second base. This makes it possible to effectively perform a selective alteration of at least a portion of the first base, which is the etching target.

In addition, in this case, the reactivity of the etching agent with the altered portion of the first base may be higher than the reactivity of the etching agent with the inhibitor layer. In addition, in this case, the reactivity of the etching agent with the altered portion of the first base may be higher than the reactivity of the etching agent with the second base. This makes it possible to effectively perform a selective etching of at least a portion of the first base, which is the etching target.

In addition, in this case, the modifying agent may include an organic substance. In addition, the modifying agent may contain at least one selected from the group of an alkyl group and an amino group. This makes it possible to effectively perform selective alteration and etching of at least a portion of the first base while suppressing alteration and etching of the second base.

In addition, in this case, the altering agent may include an oxidizing agent, and a portion of the first base may be oxidized in step B. In addition, the altering agent may further include a catalyst. This makes it possible to effectively perform the selective alteration of at least a portion of the first base. In addition, thereafter, it is possible to effectively perform the selective etching of at least a portion of the altered portion of the first base while suppressing the etching of the second base. In addition, by using the altering agent further including the catalyst, it is possible to lower the processing temperature, suppress the oxidation of the inhibitor layer, and effectively maintain the function of the inhibitor layer.

In addition, in this case, the etching agent may include a fluorine-based substance. In addition, the etching agent may contain fluorine and hydrogen. This makes it possible to effectively perform the selective etching of at least a portion of the altered portion of the first base while suppressing the etching of the second base.

In addition, in this case, the first base and the second base may be made of different materials. In addition, the first base and the second base may be alternately stacked with being adjacent to each other. In addition, the first base may contain silicon, the second base may contain silicon and oxygen, and the second base may further contain carbon. This makes it possible to more effectively produce the above-described effects. In particular, by using the second base containing carbon, the reactivity of the second base with the etching agent may be more effectively reduced than the reactivity of the altered portion of the first base with the etching agent, which makes it possible to further increase a selectivity of the selective etching of the altered portion of the first base.

After performing the cycle a predetermined number of times, the cycle including steps A, B, and C, the reaction is suppressed in regions of the surface of the second base where the inhibitor layer remains after the etching, and the subsequent processing (film formation, etching, etc.) may not proceed uniformly in the surface of the second base. In this case, by performing step D, it is possible to reset the surface of the second base and prevent the subsequent processing in the surface of the second base from being non-uniform, making it possible to perform uniform processing on the surface of the second base.

### (4) Modifications

The processing sequence in the embodiments of the present disclosure may be modified as described in the following modifications. These modifications may be combined as desired. Unless otherwise specified, processing procedures and process conditions in each step of each modification may be the same as the processing procedures and process conditions in each step of the above-described processing sequence.

### First Modification

As shown in the processing sequence below, the above-described cycle may include performing a step of alternately performing step A and step B a predetermined number of times (m₁ times, where m₁ is an integer of 1 or 2 or more) and a step of performing step C, in this order. In this modification as well, the same effects as in the above-described embodiments may be obtained. Further, according to this modification, it is possible to finely adjust an amount of alteration and an amount of etching of at least a portion of the first base, which is the etching target.

$$[ ( Modifying agent \to Altering agent ) \times {m}_{1} \to Etc hing agent ] \times n \\ [ ( Modifying agent \to Altering agent ) \times {m}_{1} \to Etc hing agent ] \times n \to Deactivating agent$$

### Second Modification

As in the processing sequence described below, the above-described cycle may include performing a step of performing step A and a step of alternately performing step B and step C a predetermined number of times (m₂ times, where m₂ is an integer of 1 or 2 or more), in this order. In this modification as well, the same effects as in the above-described embodiments may be obtained. Further, according to this modification, it is possible to finely adjust the amount of alteration and the amount of etching of at least a portion of the first base, which is the etching target.

$$[ Modifying agent \to ( Altering agent \to Etc hing agent ) \times {m}_{2} ] \times n \\ [ Modifying agent \to ( Altering agent \to Etc hing agent ) \times {m}_{2} ] \times n \to Deactivating agent$$

### Third Modification

As in the processing sequence described below, before performing step A, step E of cleaning the surface of the wafer 200 with a cleaning agent may be further performed.

$$Cleaning agent \to ( Modifying agent \to Altering agent \to Etc hing agent ) \times n \\ Cleaning agent \to ( Modifying agent \to Altering agent \to Etc hing agent ) \times n \to Deactivating agent \\ Cleaning agent \to [ \text{} ( Modifying agent \to Altering agent ) \times {m}_{1} \to Etc hing agent ] \times n \\ Cleaning agent \to [ ( Modifying agent \to Altering agent ) \times {m}_{1} \to Etc hing agent ] \times n \to Deactivating agent \\ Cleaning agent \to [ Modifying agent \to ( Altering agent \to Etc hing agent ) \times {m}_{2} ] \times n \\ Cleaning agent \to [ Modifying agent \to ( Altering agent \to Etc hing agent ) \times {m}_{2} ] \times n \to Deactivating agent$$

The cleaning agent may be a gaseous substance or a liquid substance. The cleaning agent may also be a liquid substance such as a misty substance. Examples of the cleaning agent may include the above-mentioned F-containing gas, an acetic acid (CH₃COOH) gas, a formic acid (HCOOH) gas, a hexafluoroacetylacetone (C₅H₂F₆O₂) gas, a H₂ gas, etc. In addition, as the cleaning agent, an aqueous solution of acetic acid, an aqueous solution of formic acid, various cleaning solutions to be described below, etc. may be used. One or more of these may be used as the cleaning agent.

For example, in step E, an aqueous solution of HF may be used as the cleaning agent to perform DHF cleaning on the wafer 200. In addition, for example, in step E, a cleaning solution including ammonia water, hydrogen peroxide water, and pure water may be used as the cleaning agent to perform SC-1 cleaning (APM cleaning) on the wafer 200. In addition, for example, in step E, a cleaning solution including hydrochloric acid, hydrogen peroxide water, and pure water may be used as the cleaning agent to perform SC-2 cleaning (HPM cleaning) on the wafer 200. In addition, for example, in step E, a cleaning solution including sulfuric acid and hydrogen peroxide water may be used as the cleaning agent to perform SPM cleaning on the wafer 200.

In this modification as well, the same effects as in the above-described embodiments may be obtained. In addition, according to this modification, by performing step E, for example, contaminants such as a native oxide film formed on the surface of the wafer 200 before etching can be removed, and a film formed in an uncontrolled state (a film formed under uncontrolled conditions) on the surface of the wafer 200 before etching can be removed. This makes it possible to more appropriately form an inhibitor layer on the surface of the second base with higher controllability and uniformity, and to more appropriately form an altered layer on the surface of the first base with higher controllability and uniformity. As a result, it is possible to more appropriately perform selective etching of the first base with higher controllability and uniformity.

### Other Embodiments of the Present Disclosure

The embodiments of the present disclosure are specifically described above. However, the present disclosure is not limited to the above-described embodiments, and various changes may be made without departing from the spirit of the present disclosure.

For example, the wafer 200 may include an O-free film such as the Si film, as described above, as the first base, which is the etching target. The Si film may be in any one of an amorphous state, a poly (polycrystalline) state, a mixed crystal state of amorphous and poly, and a single crystal state. That is, the Si film may be any one of an amorphous Si film, a poly Si film, a mixed crystal Si film of amorphous and poly, and an epitaxial Si film.

In addition, the wafer 200 may include a film on which an inhibitor layer is unlikely to be formed, as the first base, which is the etching target. The wafer 200 may include, as the first base, a film on which an inhibitor layer is less likely to be formed than the second base. For example, the wafer 200 may include, as the first base, a film whose surface contains less OH groups than the second base, i.e., a film on which at least a portion of the molecular structure of the molecule constituting the modifying agent is less likely to be adsorbed than the second base. The wafer 200 may include, as the first base, for example, an O-free film (non-oxide film) containing a semiconductor element, such as a silicon nitride film (SiN film), a silicon carbide film (SiC film), a silicon carbonitride film (SiCN film), a silicon boronitride film (SiBN film), a silicon borocarbonitride film (SiBCN film), a silicon borocarbide film (SiBC film), a germanium film (Ge film), or a silicon germanium film (SiGe film), in addition to the above-mentioned Si film. In addition, for example, the wafer 200 may include a plurality of types of regions of different materials, as the first base. In these embodiments as well, the same effects as in the above-described embodiments may be obtained.

In addition, for example, the wafer 200 may include a film on which an inhibitor layer is likely to be formed, as the second base, which is the non-etching target. The wafer 200 may include, as the second base, a film on which an inhibitor layer is more likely to be formed than the first base. For example, the wafer 200 may include, as the second base, a film whose surface contains more OH groups than the first base, i.e., a film on which at least a portion of the molecular structure of the molecule constituting the modifying agent is more likely to be adsorbed than the first base. The wafer 200 may include, as the second base, an O-containing film (oxide film) containing a semiconductor element, such as a silicon oxycarbonitride film (SiOCN film), a silicon oxynitride film (SiON film), a silicon borooxycarbonitride film (SiBOCN film), or a silicon borooxynitride film (SiBON film), in addition to the above-mentioned SiOC film. In addition, for example, the wafer 200 may include a plurality of types of regions of different materials, as the second base. In these embodiments as well, the same effects as in the above-described embodiments may be obtained.

Further, for example, the combination of the first base (etching target) and the second base (non-etching target) of the wafer 200 may be a combination of at least one of the various films exemplified as the first base and at least one of the various films exemplified as the second base. In this case, the inhibitor layer may be more likely to be formed on the surface of the second base than the first base. In these embodiments as well, the same effects as in the above-described embodiments may be obtained.

Recipes used in each process may be provided individually according to the processing contents and may be stored in the memory 121c via a telecommunication line or the external memory 123. Moreover, at the beginning of each process, the CPU 121a may properly select an appropriate recipe from the recipes stored in the memory 121c according to the processing contents. Thus, it is possible to perform an etching process on films of various kinds, composition ratios, qualities, and thicknesses with enhanced reproducibility in the processing apparatus. Further, it is possible to reduce an operator's burden and to quickly start each process while avoiding an operation error.

The recipes mentioned above are not limited to newly-provided ones but may be provided, for example, by modifying existing recipes that are already installed in the processing apparatus. Once the recipes are modified, the modified recipes may be installed in the processing apparatus via a telecommunication line or a recording medium storing the recipes. In addition, the existing recipes already installed in the existing processing apparatus may be directly modified by operating the input/output device 122 of the processing apparatus.

An example in which an etching process is performed by using a batch-type processing apparatus configured to process a plurality of substrates at a time is described in the above-described embodiments. The present disclosure is not limited to the above-described embodiments, but may be suitably applied, for example, to a case where an etching process is performed by using a single-wafer type processing apparatus configured to process a single substrate or several substrates at a time. In addition, an example in which an etching process is performed by using a processing apparatus provided with a hot-wall-type process furnace is described in the above-described embodiments. The present disclosure is not limited to the above-described embodiments, but may be suitably applied to a case where an etching process is performed by using a processing apparatus provided with a cold-wall-type process furnace.

In addition, an example in which the above-described processing sequence is performed in the same process chamber of the same processing apparatus (in-situ) is described in the above-described embodiments. The present disclosure is not limited to the above-described embodiments. For example, any step and any other step of the above-described processing sequence may be performed in different process chambers of different processing apparatuses (ex-situ), or may be performed in different process chambers of the same processing apparatus.

Even in the case of using these processing apparatuses, each process may be performed according to processing procedures and process conditions which are the same as those in the above-described embodiments and modifications, and effects which are the same as those of the above-described embodiments and modifications may be obtained.

The above-described embodiment and modifications may be used in proper combination. Processing procedures and process conditions used in this case may be the same as, for example, the processing procedures and process conditions in the above-described embodiments and modifications.

According to the present disclosure, it is possible to perform etching with good controllability and stability.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching method comprising:
performing a cycle a predetermined number of times, the cycle including:
(a) supplying a modifying agent to a substrate including a first base and a second base on a surface of the substrate to form an inhibitor layer on a surface of the second base;
(b) supplying an altering agent to the substrate to alter at least a portion of the first base, a molecular structure of the altering agent being different from a molecular structure of the modifying agent; and
(c) supplying an etching agent to the substrate to etch at least a portion of an altered portion of the first base.

2. The etching method of claim 1, wherein a reactivity of the modifying agent with the second base is higher than a reactivity of the modifying agent with the first base.

3. The etching method of claim 1, wherein a reactivity of the altering agent with the first base is higher than a reactivity of the altering agent with the inhibitor layer.

4. The etching method of claim 1, wherein a reactivity of the etching agent with the altered portion of the first base is higher than a reactivity of the etching agent with the inhibitor layer.

5. The etching method of claim 1, wherein a reactivity of the etching agent with the altered portion of the first base is higher than a reactivity of the etching agent with the second base.

6. The etching method of claim 1, wherein the modifying agent includes an organic substance.

7. The etching method of claim 6, wherein the modifying agent contains at least one selected from the group of an alkyl group and an amino group.

8. The etching method of claim 1, wherein the altering agent includes an oxidizing agent, and a portion of the first base is oxidized in (b).

9. The etching method of claim 8, wherein the altering agent further includes a catalyst.

10. The etching method of claim 1, wherein the etching agent includes a fluorine-based substance.

11. The etching method of claim 10, wherein the etching agent contains fluorine and hydrogen.

12. The etching method of claim 1, wherein the cycle includes performing (a), (b), and (c) in this order.

13. The etching method of claim 1, wherein the cycle includes:
performing (a) and (b) alternately a predetermined number of times; and performing (c), in this order, or
performing (a); and performing (b) and (c) alternately a predetermined number of times, in this order.

14. The etching method of claim 1, further comprising:
(d) performing at least one selected from the group of removal of the inhibitor layer remaining on the surface of the second base after the act of etching and deactivation of the inhibitor layer remaining on the surface of the second base after the act of etching.

15. The etching method of claim 1, wherein the first base and the second base are made of different materials.

16. The etching method of claim 15, wherein the first base and the second base are alternately stacked with being adjacent to each other.

17. The etching method of claim 15, wherein the first base contains silicon, and the second base contains silicon and oxygen.

18. The etching method of claim 17, wherein the second base further contains carbon.

19. A method of manufacturing a semiconductor device, comprising the etching method of claim 1.

20. A processing apparatus comprising:
a modifying agent supply system configured to supply a modifying agent to a substrate;
an altering agent supply system configured to supply an altering agent to the substrate, a molecular structure of the altering agent being different from a molecular structure of the modifying agent;
an etching agent supply system configured to supply an etching agent to the substrate; and
a controller configured to be capable of controlling the modifying agent supply system, the altering agent supply system, and the etching agent supply system so as to perform a cycle a predetermined number of times, the cycle including:
(a) supplying the modifying agent to the substrate including a first base and a second base on a surface of the substrate to form an inhibitor layer on a surface of the second base;
(b) supplying the altering agent to the substrate to alter at least a portion of the first base; and
(c) supplying the etching agent to the substrate to etch at least a portion of an altered portion of the first base.

21. A non-transitory computer-readable recording medium storing a program that causes, by a computer, a processing apparatus to perform a process comprising:
performing a cycle a predetermined number of times, the cycle including:
(a) supplying a modifying agent to a substrate including a first base and a second base on a surface of the substrate to form an inhibitor layer on a surface of the second base;
(b) supplying an altering agent to the substrate to alter at least a portion of the first base, a molecular structure of the altering agent being different from a molecular structure of the modifying agent; and
(c) supplying an etching agent to the substrate to etch at least a portion of an altered portion of the first base.
